(19) United States
(12) Patent Application Publication
(10) Pub. No.: US 2012/0122320 A1
(43) Pub. Date: May 17, 2012

(54) Method Of Processing Low K Dielectric Films

(75) Inventors: Annamalai Lakshmanan, Fremont, CA (US); Zhenjiang Cui, San Jose, CA (US); Mehul Naik, San Jose, CA (US); See-Eng Phan, Sunnyvale, CA (US); Jennifer Shan, San Jose, CA (US); Paul F. Ma, Santa Clara, CA (US)

(73) Assignee: Applied Materials, Inc., Santa Clara, CA (US)

(21) Appl. No.: 13/296,401

(22) Filed: Nov. 15, 2011

Related U.S. Application Data
(60) Provisional application No. 61/414,720, filed on Nov. 17, 2010.

(51) Int. Cl. H01L 21/318; H01L 21/31

(52) U.S. Cl. 438/785; 438/778; 257/E21.24; 257/E21.292

(57) ABSTRACT

Provided are methods for re-incorporating carbon into low-k films after processes which result in depletion of carbon from the films. Additionally, methods for replenished depleted carbon and capping with tantalum nitride are also described.

### CROSS-REFERENCE TO RELATED APPLICATIONS

This application claims priority under 35 U.S.C. §119(e) to U.S. Provisional Application No. 61/414,720, filed Nov. 17, 2011.

### BACKGROUND

Embodiments of the invention generally relate to the formation of dielectric layers during fabrication of integrated circuits on semiconductor wafers. More particularly, the present invention relates to a method for replenishing lost carbon from a low k dielectric film after ashing.

Semiconductor device geometries have dramatically decreased in size since such devices were first introduced several decades ago. Today's fabrication plants are routinely producing devices having 0.25 μm and even 0.18 μm feature sizes, and tomorrow's plants soon will be producing devices having even smaller geometries. In order to further reduce the size of devices on integrated circuits, it has become common to use conductive materials having low resistivity and insulators having a low dielectric constant. Low dielectric constant films are particularly desirable for premetal dielectric (PMD) layers and intermetal dielectric (IMD) layers to reduce the RC time delay of the interconnect metallization, to prevent cross-talk between the different levels of metallization, and to reduce device power consumption.

Undoped silicon oxide films deposited using conventional techniques may have a dielectric constant (k) as low as about 4.0 or 4.2. One approach to obtaining a lower dielectric constant is to incorporate carbon in a silicon oxide film. Low-k films often used as interlayer dielectrics are frequently carbon doped oxides with varying levels of porosity. Carbon doping makes the dielectric constant lower and renders the oxide low-k. During back end of line integration, the low-k film is etched for subsequent trenches and vias. After the etching, the photoresist is removed by an ashing process which can be, for example, an O₂ or CO₂ plasma. During the ashing process, carbon gets depleted from the low-k film. Therefore, there is a need for methods of replenishing carbon in low-k films after ashing.

### SUMMARY

One or more embodiments of the invention are directed to methods of forming semiconductor devices. A semiconductor device substrate comprising a carbon-containing low-k dielectric layer which has been exposed to a process that depletes a portion of the carbon from the low-k dielectric layer is positioned in a processing chamber. One or more of an organic carbon source or a carbon-containing organometallic complex is flowed over the low-k dielectric layer to replenish at least a portion of carbon depleted from the layer. The organic carbon source comprising a compound of the formula R₁—CH₃ or R₁(R₂)N(R₃)CH₃, wherein R₁ and R₂ are each independently hydrogen, an aliphatic group having in the range of 1 to 6 carbons, which can be substituted or unsubstituted, or an aromatic group having a ring with 2 to 8 atoms and R₃ is an aliphatic group having 0 to 6 carbons, and can be substituted or unsubstituted. The low-k dielectric film of some embodiments has a dielectric constant less than about 3.

In specific embodiments, the organic carbon source is trimethylamine, dimethylamine, methylamine and combinations thereof. In detailed embodiments, the organic carbon source is flowed for a time in the range of about 10 seconds to about 120 seconds. The substrate of some embodiments is kept at a temperature in the range of about 25° C. to about 500° C. The substrate may be processed in a process chamber at a pressure in the range of about 1 torr to about 20 torr. The organic carbon source of various embodiments is flowed with a flow rate in the range of about 200 sccm to about 2000 sccm.

Some embodiments further comprise flowing an organometallic complex over the dielectric film to provide a capping layer. In detailed embodiments, the organometallic complex comprises tantalum. In specific embodiments, the organometallic complex is pentakis(dimethylamino)tantalum. In some embodiments, the pentakis(dimethylamino)tantalum forms a TaN layer over the dielectric film. The TaN layer of specific embodiments has a thickness in the range of about 7 Å to about 40 Å. In some embodiments, the pentakis(dimethylamino)tantalum is flowed with an inert carrier gas. In detailed embodiments, the pentakis(dimethylamino)tantalum is flowed with an inert carrier gas with a flow rate in the range of about 500 sccm to about 3000 sccm.

The carbon doped low-k film of detailed embodiments is porous. The carbon doped low dielectric film of specific embodiments has an average pores size in the range of about 2 Å to about 10 Å.

In specific embodiments, both an organic carbon source and a carbon-containing organometallic complex are flowed over the low-k dielectric. The organic carbon source and carbon-containing organometallic can be flowed at the same time or in order with either being first. In certain embodiments, flowing the carbon-containing organometallic complex over the low-k dielectric layer is part of an atomic layer deposition process forming TaN.

In one or more embodiments, a hydroxide species created on the film during the etching are substituted with hydrogen by the organic carbon source.

Additional embodiments of the invention are directed to methods of forming a semiconductor device. A semiconductor device substrate comprising a carbon-containing low-k dielectric layer which has been exposed to a process that depletes a portion of the carbon from the low-k dielectric layer is positioned in a processing chamber. An organic carbon source is flowed over the depleted carbon-containing low dielectric layer to replenish at least a portion of the depleted carbon making a replenished film. The organic carbon source comprising a compound of the formula R₁—CH₃ or R₁(R₂)N(R₃)CH₃, wherein R₁ and R₂ are each independently hydrogen, an aliphatic group having in the range of 1 to 6 carbons, which can be substituted or unsubstituted, or an aromatic group having a ring with 2 to 8 atoms and R₃ is an aliphatic group having 0 to 6 carbons, and can be substituted or unsubstituted. In specific embodiments, the organic carbon source is dimethylamine. Detailed embodiments further comprise flowing pentakis(dimethylamino) tantalum over the replenished film. In specific embodiments, the low-k dielectric layer has a trench formed therin, the trench having sidewalls and a bottom, and the process that depletes carbon from the low-k dielectric layer comprises one or more of etching the low-k dielectric layer or ashing a photoresist formed on the low-k dielectric layer.

Further embodiments of the invention are directed to methods of forming a semiconductor device comprising positioning a semiconductor device substrate in a processing chamber. The device substrate comprises a carbon-containing low-k dielectric layer which has been exposed to a process that depletes a portion of the carbon from the low-k dielectric layer. A carbon-containing organometallic complex is flowed over the depleted carbon-containing low dielectric film to replenish at least a portion of the depleted carbon making a replenished film. In some embodiments, an organic carbon source is also flowed over the low-k dielectric film. The organic carbon source comprising a compound of the formula R₁—CH₃ or R₁(R₂)N(R₃)CH₃, wherein R₁ and R₂ are each independently hydrogen, an aliphatic group having in the range of 1 to 6 carbons, which can be substituted or unsubstituted, or an aromatic group having a ring with 2 to 8 atoms and R₃ is an aliphatic group having 0 to 6 carbons, and can be substituted or unsubstituted.

### BRIEF DESCRIPTION OF THE DRAWINGS

So that the manner in which the above recited features of the invention are attained and can be understood in detail, a more particular description of the invention, briefly summarized above, may be had by reference to the embodiments thereof which are illustrated in the appended drawings. It is to be noted, however, that the appended drawings illustrate only typical embodiments of this invention and are therefore not to be considered limiting of its scope, for the invention may admit to other equally effective embodiments.

FIG. 1 shows a schematic view of a process chamber according to one or more embodiments of the invention;

FIGS. 2 and 3 show expanded schematic views of channels in a gas distribution plate in accordance with one or more embodiments of the invention;

FIG. 4 shows FTIR spectra illustrating the methyl content of various films in accordance with one or more embodiments of the invention;

FIG. 5 shows a graph of the change in dielectric constant and the TaN thickness as a function of ALD cycles for samples made in accordance with one or more embodiments of the invention; and

FIG. 6 shows a graph of the change in dielectric constant and the TaN thickness as a function of ALD cycles for samples made in accordance with one or more embodiments of the invention.

### DETAILED DESCRIPTION

Embodiments of the invention are directed to methods of re-incorporating lost carbon in low-k films. While not limited to any specific technique, embodiments of the invention are commonly used in chemical vapor deposition chamber, and more specifically, in atomic layer deposition chambers.

In one or more embodiments, a methyl (—CH₃) containing fluid/gas is flowed over an ashed low-k film to reincorporate the methyl groups in the low-k film. The carbon source can be any suitable source including, for example, methyl, ethyl and propyl containing organics and carbon-containing organometallic complexes. The length of time that the carbon source is flowed can vary, for example, in the range of about 10 seconds to about 120 seconds. The temperature of the substrate can vary, for example, in the range of about 25° C. to about 500° C. The pressure in the processing chamber can vary, for example, in the range of about 1 torr to about 20 torr. In specific embodiments, the carbon source is dimethylamine.

In some embodiments, the low-k film surface is capped with, for example, about 10 A of TaN, which can be deposited by ALD processes. The cap can provide the added benefit of restoring the carbon in the low-k film in the form of —CH₃ and locally sealing the pores in the low-k surface. TaN deposition may involve a reaction between, for example, pentakis(dimethylamino)tantalum (PDMAT) and ammonia. PDMAT has 10 methyl groups that can get incorporated into the damaged low-k film.

After etching and ashing, the low-k surface may be terminated with hydroxyl (—OH) groups. These polar species are undesirable in the back end of line (BEOL) integration. Flowing an organic or metallorganic precursor over the polar low-k surface may replace the —OH bonds with —H bonds, terminating the dangling bonds leading to a stable structure, making the surface conducive to further processing.

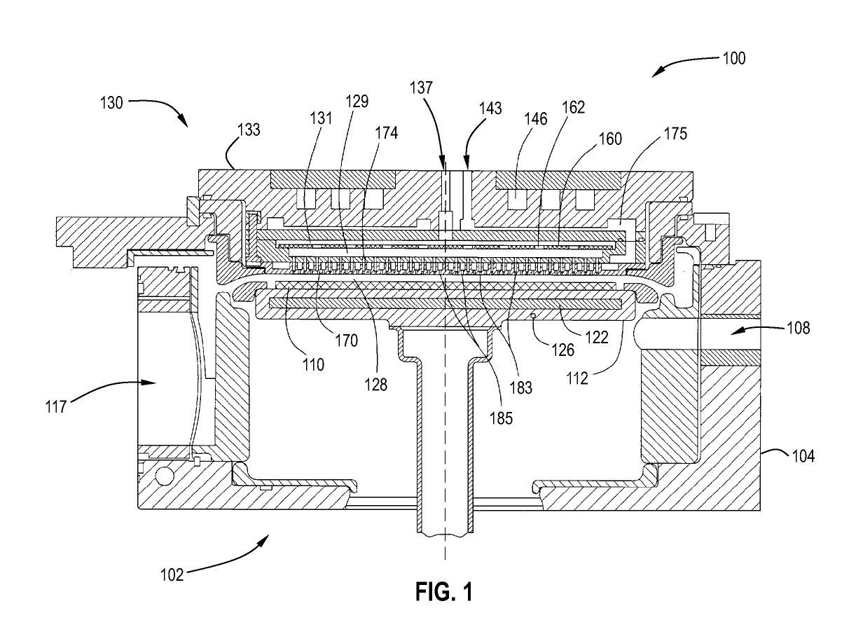

FIG. 1 shows a schematic, cross-sectional view of one or more embodiments of a process chamber 100 (e.g., ALD chamber) for performing a film deposition. The process chamber 100 comprises a chamber body 102 and a gas distribution system 130. The chamber body 102 houses a substrate support 112 that supports a substrate 110 in the chamber 100. The substrate support 112 comprises an embedded heater element 122. A temperature sensor 126 (e.g., a thermocouple) is embedded in the substrate support 112 to monitor the temperature of the substrate support 112. Alternatively, the substrate 110 may be heated using a source of radiant heat (not shown), such as quartz lamps and the like. Further, the chamber body 102 comprises an opening 108 in a sidewall 104 providing access, for example, for a robot to deliver and retrieve the substrate 110, as well as an exhaust port 117.

The gas distribution system 130 generally comprises a mounting plate 133, a showerhead 170, and a blocker plate 160 and provides at least two separate paths for gaseous compounds into a reaction region 128 between the showerhead 170 and the substrate support 112. In the depicted embodiment, the gas distribution system 130 also serves as a lid of the process chamber 100. However, in other embodiments, the gas distribution system 130 may be a portion of a lid assembly of the chamber 100. The mounting plate 133 comprises a channel 137 and a channel 143, as well as a plurality of channels 146 that are formed to control the temperature of the gaseous compounds (e.g., by providing either a cooling or heating fluid into the channels). Such control is used to prevent decomposing or condensation of the compounds. Each of the channels 137, 143 provides a separate path for a gaseous compound within the gas distribution system 130.

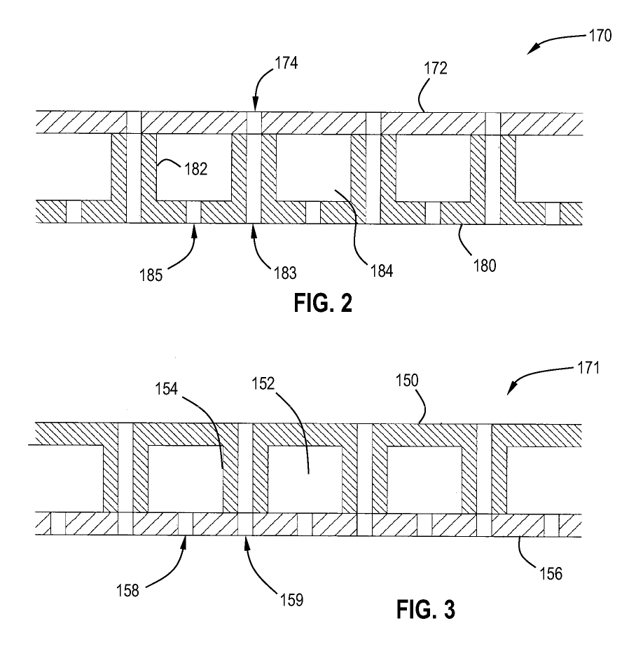

FIG. 2 is a schematic, partial cross-sectional view of one embodiment of the showerhead 170. The showerhead 170 comprises a plate 172 that is coupled to a base 180. The plate 172 has a plurality of openings 174, while the base 180 comprises a plurality of columns 182 and a plurality of grooves 184. The columns 182 and grooves 184 comprise openings 183 and 185, respectively. The plate 172 and base 180 are coupled such, that the openings 183 in the base align with the openings 174 in the plate to form a path for a first gaseous compound through the showerhead 170. The grooves 184 are in fluid communication with one another and, together, facilitate a separate path for a second gaseous compound into the reaction region 128 through the openings 185. In an alternative embodiment, shown in FIG. 3, the showerhead 171 comprises the plate 150 having the grooves 152 and columns 154, and a base 156 comprising a plurality of openings 158 and 159. In either embodiment, contacting surfaces of the plate and base may be brazed together to prevent mixing of the gaseous compounds within the showerhead.

Referring again to FIG. 1, each of the channels 137 and 143 is coupled to a source of the respective gaseous compound. Further, the channel 137 directs the first gaseous compound into a volume 131, while the channel 143 is coupled to a plenum 175 that provides a path for the second gaseous compound to the grooves 184 (shown in FIG. 2). The blocker plate 160 comprises a plurality of openings 162 that facilitate fluid communication between the volume 131, plenum 129, and a plurality of openings 174 that disperse the first gaseous compound into the reaction region 128. As such, the gas distribution system 130 provides separate paths for the gaseous compounds delivered to the channels 137 and 143.

In some embodiments, the blocker plate 160 and the showerhead 170 are electrically isolated from one another, the mounting plate 133, and chamber body 102 using insulators (not shown) formed of, for example, quartz, ceramic, and the like. The insulators are generally disposed between the contacting surfaces in annular peripheral regions thereof to facilitate electrical biasing of these components and, as such, enable plasma enhanced cyclical deposition techniques, e.g., plasma enhanced ALD (PEALD) processing.

In one exemplary embodiment, a power source may be coupled, e.g., through a matching network (both not shown), to the blocker plate 160 when the showerhead 170 and chamber body 102 are coupled to a ground terminal. The power source may be one or more of a radio-frequency (RF) or direct current (DC) power source that energizes the gaseous compound in the plenum 129 to form a plasma. Alternatively, the power source may be coupled to the showerhead 170 when the substrate support 112 and chamber body 102 are coupled to the ground terminal. In this embodiment, the gaseous compounds may be energized to form a plasma in the reaction region 128. As such, the plasma may be selectively formed either between the blocker plate 160 and showerhead 170, or between the showerhead 170 and substrate support 112.

One or more embodiments of the invention are directed to methods of forming semiconductor devices. A semiconductor device substrate comprising a carbon-containing low-k dielectric layer which has been exposed to a process that depletes a portion of the carbon from the low-k dielectric layer is positioned in the processing chamber. One or more of an organic carbon source and a carbon-containing organometallic complex is flowed over the low-k dielectric layer to replenish at least a portion of carbon depleted from the layer. The low-k dielectric layer generally has a dielectric constant less than about 3.

In more specific embodiments, the low-k dielectric layer has a dielectric constant, after replenishing the carbon content, that is less than or equal to about 3.5, 3.4, 3.3, 3.2, 3.1, 3.0, 2.9, 2.8, 2.7, 2.6, 2.5, 2.4, 2.3, 2.2, 2.1, 2.0, 1.9, 1.8, 1.7, 1.6 or 1.5. In certain embodiments, the dielectric constant of the low-k dielectric layer is lower after replenishing the carbon than before.

The organic carbon source can be any suitable compound which can provide a methyl group. In some embodiments, the organic carbon source comprises a compound of the formula R₁—CH₃ or R₁(R₂)N(R₃)CH₃, wherein R₁ and R₂ are each independently hydrogen, an aliphatic group having in the range of 1 to 6 carbons, which can be substituted or unsubstituted, or an aromatic group having a ring with 2 to 8 atoms. R₃ is an aliphatic group having 0 to 6 carbons, and can be substituted or unsubstituted. In specific embodiments the carbon source is an amine. The amine of detailed embodiments is one or more of trimethylamine (TMA), dimethylamine (DMA) and methylamine.

In various embodiments the carbon source can be an organometallic complex (also referred to as a metallorganic) having the general formula M-(N—R₁R₂)ₓ, where M is a metal, N is nitrogen, x is in the range of 0 and 4, and R₁ and R₂ are each independently hydrogen, aliphatic group having 0 to 6 carbons, which can be substituted or unsubstituted, aromatic groups having ring including 0 to 10 atoms, which can be substituted or unsubstituted. The metal can be any suitable metal and may or may not be incorporated into the semiconductor device. Stated differently, the metallorganic complex may contribute only methyl groups to the low-k film or may contribute a metal species to the semiconductor device (e.g., capping). In various embodiments the metal is a transition metals. In specific embodiments, the metal is one or more of tantalum, titanium, hafnium, zirconium, manganese, cobalt and molybdenum. In detailed embodiments, the metal is tantalum.

The processes described are effective to replenish lost carbon in the low-k dielectric layer. In some embodiments, greater than about 20% of the depleted carbon is replenished. In various embodiments, greater than or equal to about 25%, 30%, 35%, 40%, 45%, 50%, 55%, 60%, 65%, 70%, 75%, 80%, 85%, 90%, 95% or 100% of the depleted carbon is replenished. In some embodiments, after treating the surface with the carbon source, there is more carbon in the low-k dielectric than before the depletion occurred.

The low-k dielectric layer of some embodiments has at least one trench formed therein. The trench having sidewalls and a bottom, and the process that depletes carbon from the low-k dielectric layer comprises one or more of etching the low-k dielectric layer or ashing a photoresist formed on the low-k dielectric layer.

In detailed embodiments, the low-k dielectric layer is formed over a copper substrate or copper layer. The bottom of the trenches expose the copper and the sidewalls of the trenches is the low-k dielectric. The processes described can separately or simultaneously for a TaN layer over the copper and repair damage to the low-k dielectric sidewalls.

The processing conditions may impact the effectiveness of the carbon source and may be optimized for individual carbon sources. In detailed embodiments, the substrate is kept at a controlled temperature in the range of about 25° C. to about 500° C. As used in this specification and the appended claims, the term “controlled temperature” means that there is some mechanical or physical control over the temperature (e.g., radiant heat sources). The controlled temperature is maintained within about 50° C. of the target temperature, or within about 40° C. of the target temperature, or within about 30° C. of the target temperature, or within about 20° C. of the target temperature, or within about 10° C. of the target temperature. In various embodiments, the substrate is kept at a controlled temperature in the range of about 100° C. to about 400° C., or in the range of about 200° C. to about 350° C. In specific embodiments, the substrate is processed at a controlled temperature of about 275° C. In various embodiments, the substrate temperature is greater than about 25° C., 50° C., 75° C., 100° C., 125° C., 150° C., 175° C., 200° C., 225° C., 250° C., 275° C., 300° C., 325° C., 350° C., 375° C., 400° C., 425° C., 450° C., 475° C. or 500° C.

The pressure range of the process can be varied as required. In some embodiments, the substrate is processed in a chamber at a pressure in the range of about 0.5 torr to about 50 torr. In various embodiments, the substrate is processed in a chamber at a pressure in the range of about 1 torr to about 20 torr, or in the range of about 1.5 torr to about 10 torr or in the range of about 2 torr to about 4 torr. In specific embodiments, the substrate is processed in a chamber with a pressure greater than or equal to about 0.5 torr, 1 torr, 1.5 torr, 2 torr, 3 torr, 4 torr, 5 torr, 6 torr, 7 torr, 8 torr, 9 torr and 10 torr.

The carbon source can be flowed for a variable length of time and flow rate, depending on the specific compounds used, the vapor pressure, flow rate, temperature, etc. In some embodiments, the organic carbon source is flowed for a time in the range of about 2 seconds to about 300 seconds, or in the range of about 3 seconds to about 240 second, or in the range of about 7 seconds to about 180 seconds or in the range of about 10 seconds to about 120 seconds. In various embodiments, the organic carbon source is flowed for a time greater than or equal to about 1 second, 2 seconds, 3 seconds, 4 seconds, 5 seconds, 6 seconds, 7 seconds, 8 seconds, 9 seconds, 10 seconds, 15 seconds, 20 seconds, 25 seconds, 30 seconds, 35 seconds, 40 seconds, 45 seconds, 50 seconds, 55 seconds, 60 seconds, 90 seconds, 120 seconds, 150 seconds, 180 seconds, 210 seconds, 240 seconds, 300 seconds, 330 seconds or 360 seconds. The organic carbon source in some embodiments is flowed with a flow rate in the range of about 50 sccm to about 4000 sccm, or in the range of about 100 sccm to about 3000 sccm, or in the range of about 200 sccm to about 2000 sccm or in the range of about 300 sccm to about 1500 sccm.

Some embodiments further comprise flowing an organometallic complex over the dielectric film to provide a capping layer. This organometallic complex can be a different complex than the one used to replenish carbon or the same complex. The processes can be done separately or simultaneously. In specific embodiments the organometallic complex comprises tantalum. In more specific embodiments, the organometallic complex is pentakis(dimethylamino)tantalum (PDMAT). When necessary, the organometallic complex can be flowed with an inert carrier gas. This may be common where the organometallic complex is a liquid or solid. In specific embodiments, PDMAT is flowed with an inert carrier gas with a flow rate in the range of about 500 sccm to about 3000 sccm.

In some embodiments, the PDMAT, or other organometallic complex, is flowed over the damaged low-k film without previously flowing a separate amine. The PDMAT, or other organometallic complex, can be used to replenish eh carbon in the low-k film, can be used to form a capping layer over the low-k film or both. In specific embodiments, a tantalum nitride (TaN) layer is formed over the replenished low-k film after PDMAT is flowed over the film to replenish the carbon.

The thickness of the TaN layer can be varied depending on the desired properties of the resultant semiconductor. In detailed embodiments, the TaN layer has a thickness in the range of about 7 Å to about 40 Å. In specific embodiments, the TaN layer has a thickness of about 10 Å. In various embodiments, the thickness of the TaN layer is greater than or equal to about 1 Å, 2 Å, 3 Å, 4 Å, 5 Å, 6 Å, 7 Å, 8 Å, 9 Å, 10 Å, 15 Å, 20 Å, 25 Å, 30 Å, 35 Å or 40 Å.

In specific embodiments, the dielectric film is porous. The pores can have an average pore size in the range of about 1 Å to about 20 Å. In detailed embodiments, the pores have an average size in the range of about 2 Å to about 10 Å. In specific embodiments, the average pore size is in the range of about 5 Å to about 7 Å. In various embodiments, the low-k film has pores with an average size greater than or equal to about 1 Å, 2 Å, 3 Å, 4 Å, 5 Å, 6 Å, 7 Å, 8 Å, 9 Å, 10 Å or 15 Å.

In some embodiments, in addition to depleting the carbon source, or in place of depleting the carbon from the low-k dielectric, the processing conditions may result in the formation of hydroxide species on the film. In detailed embodiments, the carbon source is effective to substitute the hydroxide with hydrogen, removing dangling bonds from the low-k film.

Additional embodiments of the invention are directed to methods of forming a semiconductor device in which a substrate is positioned in a processing chamber. The substrate comprises a carbon-containing low-k dielectric layer which has been exposed to a process that depletes a portion of the carbon from the low-k dielectric film. Dimethylamine is flowed over the carbon-containing low-k film to replenish at least a portion of the depleted carbon, making a replenished film. In specific embodiments, pentakis(diemthylamino)tantalum is flowed over the replenished film to form a TaN capping layer over the low-k dielectric film.

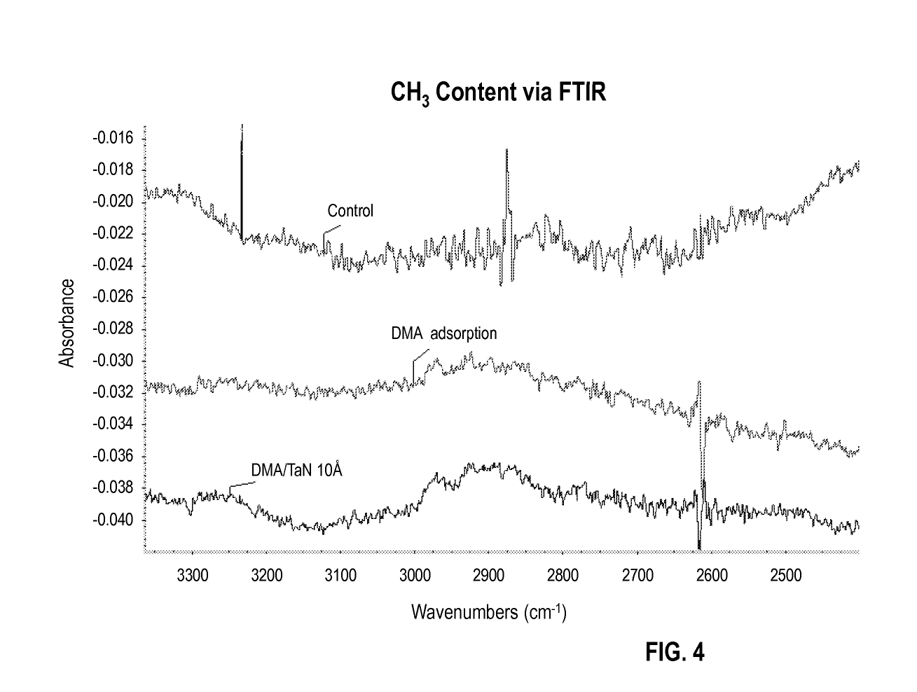

FIG. 4 shows a three FTIR spectra for various low-k dielectric films which deposited under similar conditions and were ashed for 15 seconds with a bias power of 200 W, a pressure of 5 mTorr, a CO₂ flow rate of 200 sccm and a temperature of 60° C. The top spectrum is a control in which there was no replenishment of the carbon after ashing. The middle spectrum was replenished with dimethylamine after ashing. The bottom spectrum was replenished with dimethylamine and capped with 10 Å of TaN. It can be seen that the methyl peak (˜2618 cm⁻¹) is larger for the replenished films than for the control.

### EXAMPLES

Comparative Sample 1

Carbon doped silicon oxide having a thickness of about 2000 Å was deposited onto a silicon substrate. The dielectric constant of this film was determined. TaN was deposited on the carbon doped silicon oxide by sequentially exposing the film to pentakis(dimethylamino)tantalum (PDMAT) and ammonia for up to 40 cycles. The dielectric constant of the low-k dielectric was determined again.

Sample 2

Carbon doped silicon oxide having a thickness of about 2000 Å was deposited onto a silicon substrate. The dielectric constant of the low-k dielectric was determined. The film was ashed by exposure to an oxygen rich plasma—a process which depletes carbon. The dielectric constant of the low-k dielectric was determined. TaN was deposited on the low-k dielectric by sequential exposure to pentakis(dimethylamino) tantalum (PDMAT) and ammonia for up to 40 cycles. The dielectric constant of the low-k dielectric was determined again.

Comparative Sample 3

Carbon doped silicon oxide having a thickness of about 2000 Å was deposited onto a silicon substrate with a porogen. The porogen was removed by exposure of the film to an electron beam or UV treatment. The resultant film had pores with an average pore size of about 1 nm. The dielectric constant of the resulting porous film was determined. TaN was deposited on the porous low-k dielectric by sequential exposure to pentakis(dimethylamino)tantalum (PDMAT) and ammonia for up to 40 cycles. The dielectric constant of the low-k dielectric was determined again.

Sample 4

Carbon doped silicon oxide having a thickness of about 2000 Å was deposited onto a silicon substrate with a porogen. The pyrogen was removed by exposure of the film to an electron beam or UV treatment. The resultant film had pores with an average pore size of about 1 nm. The dielectric constant of the resulting porous film was determined. The film was ashed by exposure to an oxygen rich plasma—a process which depletes carbon. The dielectric constant of the low-k dielectric was determined. TaN was deposited on the ashed porous low-k dielectric by sequential exposure to pentakis(dimethylamino)tantalum (PDMAT) and ammonia for up to 40 cycles. The dielectric constant of the low-k dielectric was determined again.

The results of the dielectric testing are shown in Table 1.

TABLE 1

| Sample | Before Ashing | After Ashing | After 40 cycles TaN |
|---|---|---|---|
| 2 | 2.62 | 3.07 | 3.00 |
| 4 | 3.26 | 3.48 | 3.32 |

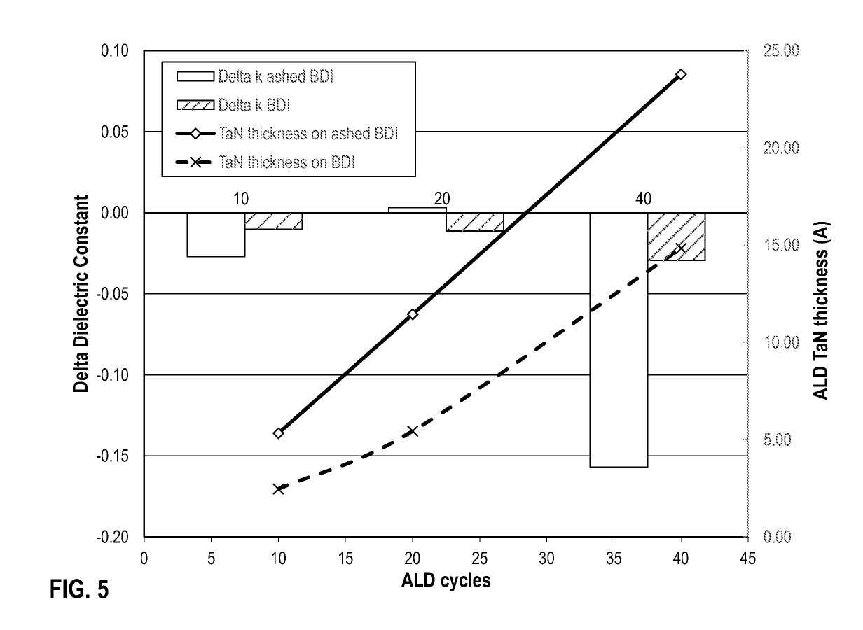

FIG. 5 shows a graph of the change in dielectric constant and the TaN thickness as a function of the number of ALD TaN cycles for Comparative Sample 1 and Sample 2. It can be seen that the thickness of the ALD TaN film grows at a faster rate for the ashed sample (Sample 2) than the unashed sample (Comparative Sample 1). It can also be seen that the change in the dielectric constant increases with the number of TaN cycles (correlating to the TaN thickness).

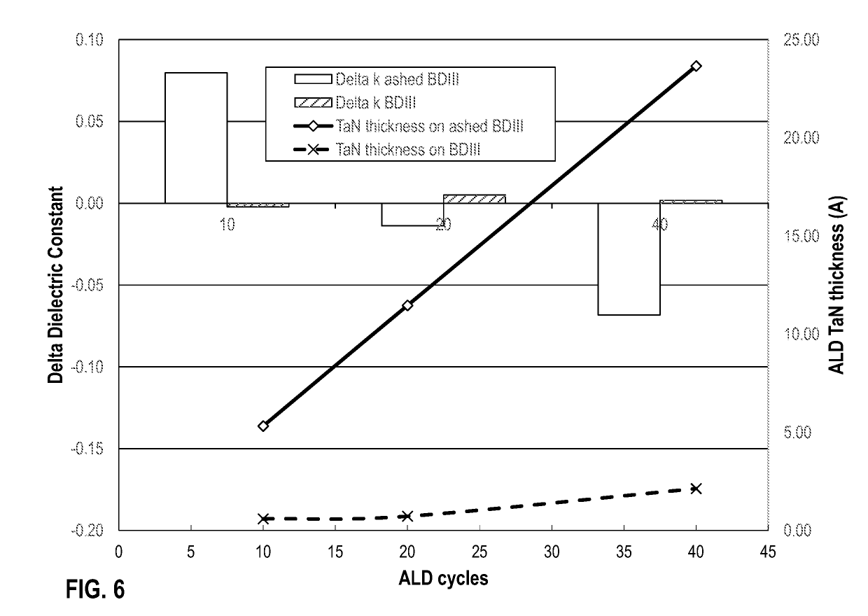

FIG. 6 shows a graph of the change in dielectric constant and the TaN thickness as a function of the number of ALD TaN cycles for Comparative Sample 3 and Sample 4. It can be seen that the thickness of the ALD TaN film grows at a faster rate for the ashed sample (Sample 4) than the unashed sample (Comparative Sample 3). It can also be seen that the change in the dielectric constant increases with the number of TaN cycles (correlating to the TaN thickness).

Although the invention herein has been described with reference to particular embodiments, it is to be understood that these embodiments are merely illustrative of the principles and applications of the present invention. It will be apparent to those skilled in the art that various modifications and variations can be made to the method and apparatus of the present invention without departing from the spirit and scope of the invention. Thus, it is intended that the present invention include modifications and variations that are within the scope of the appended claims and their equivalents.

What is claimed is:

1. A method of forming semiconductor device, comprising positioning in a processing chamber a semiconductor device substrate comprising a carbon-containing low-k dielectric layer which has been exposed to a process that depletes a portion of the carbon from the low-k dielectric layer; and; flowing one or more of an organic carbon source or carbon-containing organometallic complex over the low-k dielectric layer to replenish at least a portion of carbon depleted from the layer, the organic carbon source comprising a compound of the formula R₁—CH₃ or R₁(R₂)N(R₃)CH₃, wherein R₁ and R₂ are each independently hydrogen, an aliphatic group having in the range of 1 to 6 carbons, which can be substituted or unsubstituted, or an aromatic group having a ring with 2 to 8 atoms and R₃ is an aliphatic group having 0 to 6 carbons, and can be substituted or unsubstituted.

2. The method of claim 1, wherein the organic carbon source is dimethylamine.

3. The method of claim 1, wherein the organometallic complex has a general formula M-(N—R₁R₂)ₓ, where M is a metal, N is nitrogen, x is in the range of 0 and 4, and R₁ and R₂ are each independently hydrogen, aliphatic group having 0 to 6 carbons, which can be substituted or unsubstituted, aromatic groups having ring including 0 to 10 atoms, which can be substituted or unsubstituted.

4. The method of claim 1, wherein both an organic carbon source and a carbon-containing organometallic complex are flowed over the low-k dielectric layer.

5. The method of claim 1, wherein flowing the carbon-containing organometallic complex over the low-k dielectric layer is part of an atomic layer deposition process forming TaN.

6. The method of claim 1, wherein the organometallic complex comprises tantalum.

7. The method of claim 1, wherein the organometallic complex comprises pentakis(dimethylamino)tantalum.

8. The method of claim 7, wherein the pentakis(dimethylamino)tantalum forms a TaN layer over the low-k dielectric film.

9. The method of claim 8, wherein the TaN layer has a thickness in the range of about 7 Å to about 40 Å.

10. The method of claim 7, wherein the pentakis(dimethylamino)tantalum is flowed with an inert carrier gas.

11. The method of claim 10, wherein the pentakis(dimethylamino)tantalum is flowed with an inert carrier gas with a flow rate in the range of about 500 sccm to about 3000 sccm.

12. The method of claim 1, wherein the carbon doped low-k dielectric film is porous.

13. The method of claim 12, wherein the carbon doped low-k dielectric film has average pores size in the range of about 2 Å to about 20 Å.

14. The method of claim 1, wherein hydroxide species created on the low-k dielectric film during etching are substituted with hydrogen by the organic carbon source.

15. A method of forming a semiconductor device comprising:
positioning in a processing chamber a semiconductor device substrate comprising a carbon-containing low-k dielectric layer which has been exposed to a process that depletes a portion of the carbon from the low-k dielectric layer; and
flowing an organic carbon source over the depleted carbon-containing low dielectric film to replenish at least a portion of the depleted carbon making a replenished film, the organic carbon source comprising a compound of the formula R₁—CH₃ or R₁(R₂)N(R₃)CH₃, wherein R₁ and R₂ are each independently hydrogen, an aliphatic group having in the range of 1 to 6 carbons, which can be substituted or unsubstituted, or an aromatic group having a ring with 2 to 8 atoms and R₃ is an aliphatic group having 0 to 6 carbons, and can be substituted or unsubstituted.

16. The method of claim 15, wherein the organic carbon source comprises dimethylamine.

17. The method of claim 15, further comprising flowing pentakis(dimethylamino) tantalum over the replenished film.

18. The method of claim 15, wherein the low-k dielectric layer has a trench formed therein, the trench having sidewalls and a bottom, and the process that depletes carbon from the low-k dielectric layer comprises one or more of etching the low-k dielectric layer or ashing a photoresist formed on the low-k dielectric layer.

19. A method of forming a semiconductor device comprising:
positioning in a processing chamber a semiconductor device substrate comprising a carbon-containing low-k dielectric layer which has been exposed to a process that depletes a portion of the carbon from the low-k dielectric layer; and
flowing a carbon-containing organometallic complex over the depleted carbon-containing low-k dielectric film to replenish at least a portion of the depleted carbon making a replenished film.

20. The method of claim 19, further comprising flowing an organic carbon source over the low dielectric film, the organic carbon source comprising a compound of the formula R₁—CH₃ or R₁(R₂)N(R₃)CH₃, wherein R₁ and R₂ are each independently hydrogen, an aliphatic group having in the range of 1 to 6 carbons, which can be substituted or unsubstituted, or an aromatic group having a ring with 2 to 8 atoms and R₃ is an aliphatic group having 0 to 6 carbons, and can be substituted or unsubstituted.
